(19) United States
(12) Patent Application Publication
(10) Pub. No.: US 2008/0297164 A1
(43) Pub. Date: Dec. 4, 2008

(54) WIRING ANALYZER ADAPTER

(75) Inventors: Francisco Carpio, Overland Park, KS (US); Gary D. Mullins, Lake Tapawingo, MO (US)

Correspondence Address: HOVEY WILLIAMS LLP, 10801 Mastin Blvd., Suite 1000, Overland Park, KS, 66210, US

(73) Assignee: DIT-MCO INTERNATIONAL CORPORATION, Kansas City, MO (US)

(21) Appl. No.: 11/755,913

(22) Filed: May 31, 2007

(51) Int. Cl. G01R 31/02; H01R 31/08

(52) U.S. Cl. 324/537; 324/539; 439/507; 439/512

(57) ABSTRACT

An adapter for connecting a wiring cable to be tested to a wiring analyzer. The adapter includes a body; a first set of contacts positioned on a first side of the body for electrically connecting with the wiring analyzer; and a second set of contacts positioned on a second side of the body and electrically connected to the first set of contacts for connecting with a connector on the cable to be tested. The first and second sides of the body are less than 4 inches apart so that the first set of contacts is positioned less than 4 inches from the second set of contacts. The body may include hanging structure for hanging the adapter on an interface of the wiring analyzer and a latch for securing the adapter to the interface.

### BACKGROUND

1. Field

The present invention relates to wiring analyzers for testing wiring cables. More particularly, the invention relates to adapters for quickly and easily connecting wiring cables to be tested to a wiring analyzer without the use of long and cumbersome adapter cables.

2. Description of the Related Art

Wiring analyzers are used to test the wiring and other electrical conductors of aircraft and other vehicles, components, and devices with critical wiring. Wiring analyzers may, for example, perform circuit continuity tests for open circuits, insulation resistance tests for short circuits, dielectric breakdown (hipot) tests, resistor tests, relay tests, diode tests, capacitor tests, and switch and circuit breaker tests.

To test a wiring cable, the cable must first be connected to the wiring analyzer or to an interface connected to the wiring analyzer. This is sometimes difficult because cables to be tested typically terminate in one or more of a myriad of different connectors. For example, a typical aircraft to be tested may have hundreds of wiring cables to be tested, many of which may terminate in a different type of connector. It has therefore been necessary to provide adapter cables for connecting wiring cables with different types of connectors to a wiring analyzer. A separate adapter cable is required for each type of connector on the wiring cables to be tested, thus requiring a large number of adapter cables. Those skilled in the art will appreciate that adapter cables are relatively expensive, cumbersome to use, difficult to store, and prone to damage during use and storage. Because the adapter cables are prone to damage, they must be tested for open circuits, short circuits, etc. before they can be used to test the wiring of a vehicle or product, thus significantly increasing testing time.

Accordingly, there is a need for an improved adapter for use with wiring analyzers that overcomes the limitations of the prior art.

### SUMMARY

The present invention solves the above-described problems and provides a distinct advance in the art of wiring analyzers and adapters for use with wiring analyzers.

One embodiment of the invention is an adapter for connecting a wiring cable to be tested to a wiring analyzer. The adapter broadly comprises a body; a first set of contacts positioned on a first or front side of the body for electrically connecting with the wiring analyzer; and a second set of contacts positioned on a second or rear side of the body and electrically connected to the first set of contacts for connecting with a connector on the cable to be tested.

The body may be generally rectangular in cross-section and formed of rigid material such as metal. The first and second sides of the body are preferably less than 4 inches apart so that the first set of contacts is positioned less than 4 inches from the second set of contacts. The body may include hanging structure for hanging the adapter on an interface of the wiring analyzer and a latch for securing the adapter to the interface.

The first set of contacts may consist of a plurality of electrically conductive pins for connecting with a plurality of female-type electrically connectors on the wiring analyzer interface. The second set of contacts may be contained within one or more connectors mounted on the second side of the body.

Importantly, the adapter may be provided with any type, configuration, and number of contacts on the second side of the body for connecting with any type of connector on a cable to be tested. For example, when a cable to be tested includes a round 55 pin male-type connector, the adapter may include a corresponding round 55 pin female-type socket connector. The adapter may also include multiple connectors on the second side of the body for connecting with more than one cable to be tested or a single cable with multiple connectors.

Another embodiment of the invention is a wiring testing assembly broadly comprising a wiring analyzer and first and second adapters for connecting first and second wiring cables to be tested to the wiring analyzer. The wiring analyzer has a switch matrix and an interface electrically connected with the switch matrix.

Each of the first and second adapters includes a body having first and second opposed sides and hanging structure for hanging the adapter on the wiring analyzer; a plurality of electrically conductive pins positioned on the first side of the body for electrically connecting with the interface of the wiring analyzer; and a connector positioned on the second side of the body and electrically connected to the pins for connecting with a connector on the first cable to be tested.

In use, several of the adapters may be provided for coupling with several wiring cables to be tested. For example, a first adapter with a round 55 pin connector and a second adapter with a rectangular 50 pin connector may be simultaneously used to couple a pair of wiring cables to be tested to the wiring analyzer. The relatively small size, low cost, and durability of the adapters makes it convenient and economical to provide a separate adapter for each connector type on the cables to be tested. The adapters can be easily and safely stored without significant risk of damage when not in use and can be used in any combination and quantity to accommodate any testing requirement.

These and other important aspects of the present invention are described more fully in the detailed description below.

### BRIEF DESCRIPTION OF THE DRAWING FIGURES

A preferred embodiment of the present invention is described in detail below with reference to the attached drawing figures, wherein:

FIG. 1 is a schematic view illustrating a wiring cable under test shown connected to an adapter constructed in accordance with an exemplary embodiment of the invention, which is in turn connected to a wiring analyzer.

FIG. 2 is a side view of the exemplary wiring analyzer adapter of FIG. 1.

FIG. 3 is a front view of the adapter of FIG. 2.

FIG. 4 is a rear view of the adapter of FIG. 2.

FIG. 5 is a top view of the adapter of FIG. 2.

FIG. 6 is a side view of another exemplary wiring analyzer adapter constructed in accordance with another embodiment of the present invention.

FIG. 7 is a front view of the adapter of FIG. 6.

FIG. 8 is a rear view of the adapter of FIG. 6.

FIG. 9 is a top view of the adapter of FIG. 6.

FIG. 10 is a side view of another exemplary wiring analyzer adapter constructed in accordance with another embodiment of the present invention.

FIG. 11 is a front view of the adapter of FIG. 10.

FIG. 12 is a rear view of the adapter of FIG. 10.

FIG. 13 is a top view of the adapter of FIG. 10.

FIG. 14 is a side view of an exemplary adapter before it has been attached to an interface of a wiring analyzer.

FIG. 15 is a side view of the adapter of FIG. 12 shown partially attached to the interface.

FIG. 16 is a side view of the adapter of FIG. 12 shown fully attached to the interface.

FIG. 17 is a side view of another exemplary wiring analyzer adapter constructed in accordance with another embodiment of the present invention.

FIG. 18 is a front view of the adapter of FIG. 17.

FIG. 19 is a rear view of the adapter of FIG. 17.

FIG. 20 is a top view of the adapter of FIG. 17.

The drawing figures do not limit the present invention to the specific embodiments disclosed and described herein. The drawings are not necessarily to scale, emphasis instead being placed upon clearly illustrating the principles of the invention.

### DETAILED DESCRIPTION

The following detailed description of the invention references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the invention. The following detailed description is, therefore, not to be taken in a limiting sense. The scope of the present invention is defined only by the appended claims, along with the full scope of equivalents to which such claims are entitled.

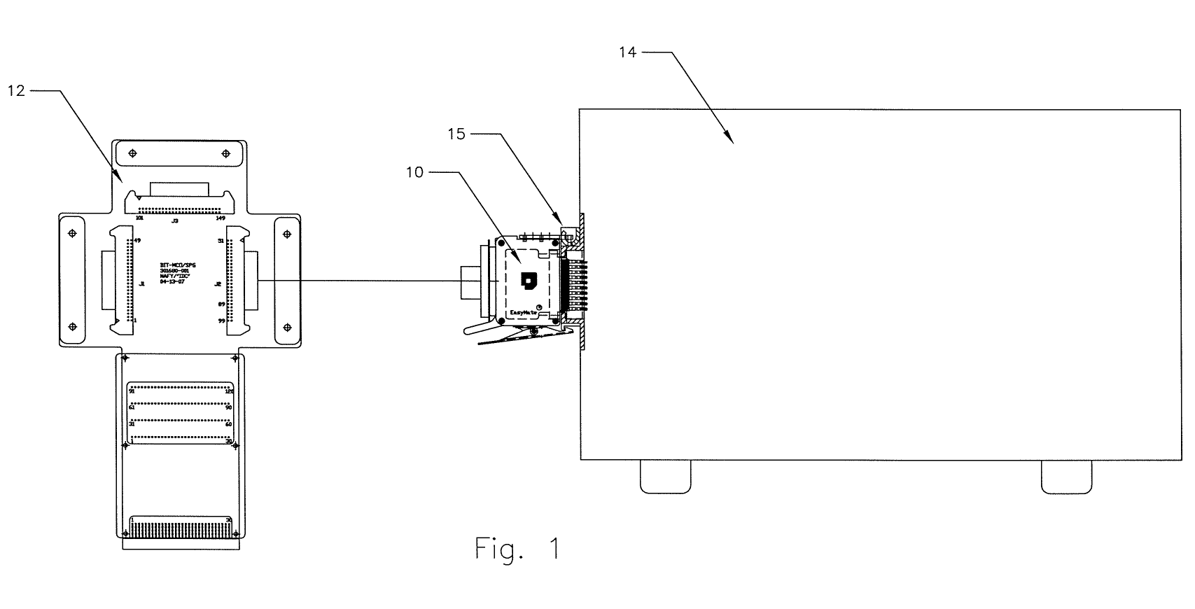

Turning now to the drawing figures, and particularly FIG. 1, an adapter 10 constructed in accordance with an embodiment of the invention is shown connecting a wiring cable 12 to be tested to a wiring analyzer 14. As used herein, the term “wiring cable” is meant to encompass all types of wires, cables, conductors, and other conductive elements capable of carrying an electric current. For example, the wiring cable may be, but is not limited to, a wire or group of wires from an aircraft or other vehicle, component, or device. The wiring analyzer may be any conventional analyzer such as the Model 2650.MTA analyzer provided by DIT-MCO International. The wiring analyzer 14 may include an interface 15 with any number of test points electrically connected with a switching module or matrix. The wiring analyzer may also include a random hook-up feature which reads or detects a bar code, embedded ID, or electrical signature of the adapter 10 so that the wiring analyzer 14 can automatically detect the type of wiring cable that is being tested and run a particular test program.

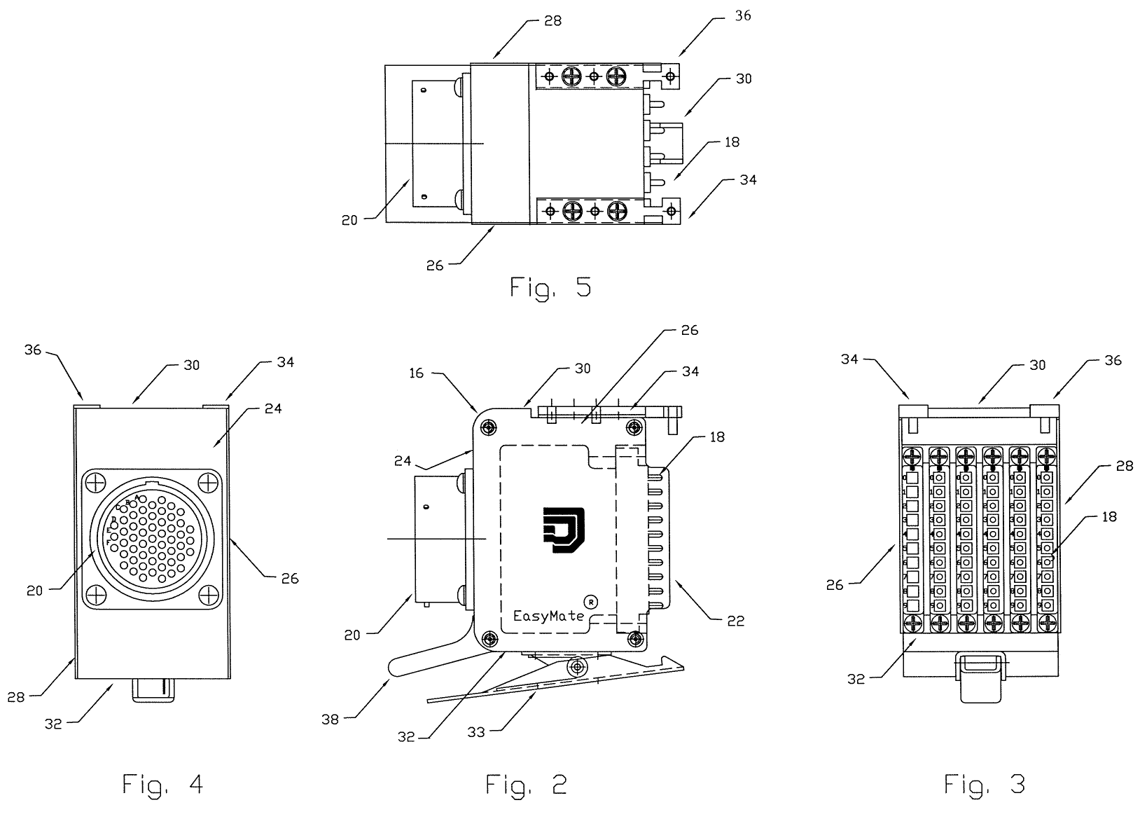

Turning now to FIGS. 2-5, one embodiment of the adapter 10 broadly comprises a body 16; a first set of contacts 18 positioned on a front or first side of the body for electrically connecting with the wiring analyzer; and a second set of contacts 20 positioned on a rear or second side of the body and electrically connected to the first set of contacts for connecting with a connector on a cable to be tested.

The body 16 may be generally rectangular in cross-section and includes a front side 22, a rear side 24, a left sidewall 26, a right sidewall 28, a top wall 30 and a bottom wall 32. The body is preferably formed of rigid material such as metal but may be formed of other materials such as plastic, fiberglass, composites, etc.. The front 22 and rear 24 sides of the body are preferably less than 4 inches apart so that the first set of contacts is positioned less than 4 inches from the second set of contacts. In a specific embodiment, the body is approximately 2 inches thick (measured from the front side to the rear side), approximately 1¾ inches wide (measured from the left sidewall to the right sidewall), and approximately 2¾ inches tall (measured from the top wall to the bottom wall). In other embodiments, the body may be bigger or smaller to accommodate connectors of various shapes and sizes as discussed in more detail below. Thus, the body may be formed in any shape or size without departing from the scope of the claims set forth in the application.

The body 16 may include hanging structure for hanging the adapter on the interface 15 of the wiring analyzer 14 and a latch 33 for securing the adapter to the interface. In one embodiment, the hanging structure includes a pair of bars 34, 36 mounted to the top wall 30 of the body. As best illustrated in FIGS. 3 and 5, each bar includes a portion with notched sides and a depending pin which overhangs the front side of the body. The hanging structure couples with a corresponding rack 37 on the wiring analyzer interface 15 as described in more detail below.

The latch 33 may be secured to the bottom wall 32 of the body 16. The latch is shiftable between a closed position shown in the drawing figures and an open position and is biased toward its closed position by an internal spring or other mechanism. The body may also include a downwardly angled gripping flange 38 for facilitating gripping of the adapter and for serving as a stop for the latch 33.

The first set of contacts 18 on the front side 22 of the body may consist of a plurality of electrical conductive pins for connecting with a plurality of female-type electrically connectors on the interface of the wiring analyzer. For example, as illustrated in FIG. 3, the adapter may include 5 columns or arrays of pins with each column or array having 10 individual pins. However, the present invention is not limited to any particular number or type of contacts, and in fact contemplates different adapters with different numbers and types of contacts so that any wiring cable with any type of connector can be connected to the wiring analyzer 14.

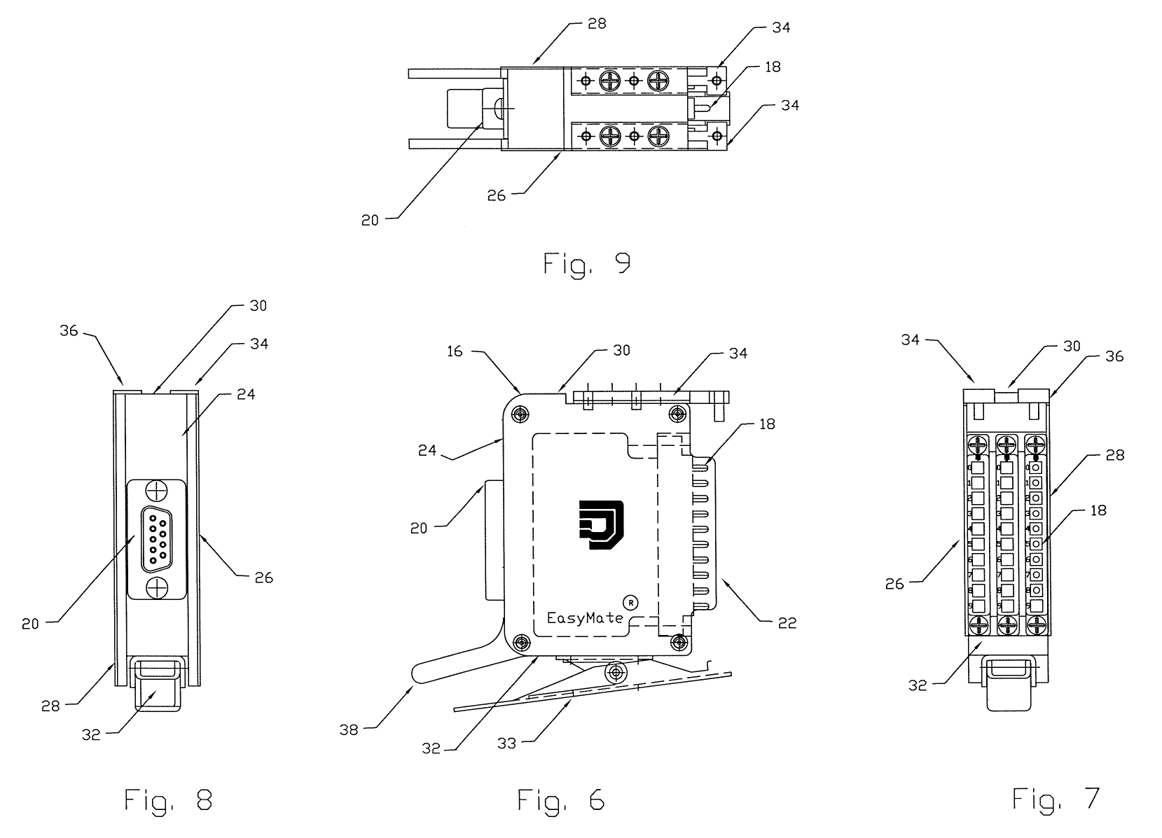

The second set of contacts 20 are electrically connected to the first set of contacts 18 by wires or other conductors and may be contained within one or more connectors mounted on the second side 24 of the body. For example, in one embodiment illustrated in FIG. 4, the contacts are contained in a round, female-type, 55 pin socket connector configured for coupling with a corresponding round, male-type 55 pin connector on a wiring cable to be tested. In another embodiment illustrated in FIGS. 6-9, the contacts are contained in a rectangular, female-type 50 pin socket connector configured for coupling with a corresponding male-type connector on a wiring cable. Importantly, the adapter may be provided with any type and configuration of contacts on the second or rear side of the body for connecting with any type of connector on a cable to be tested.

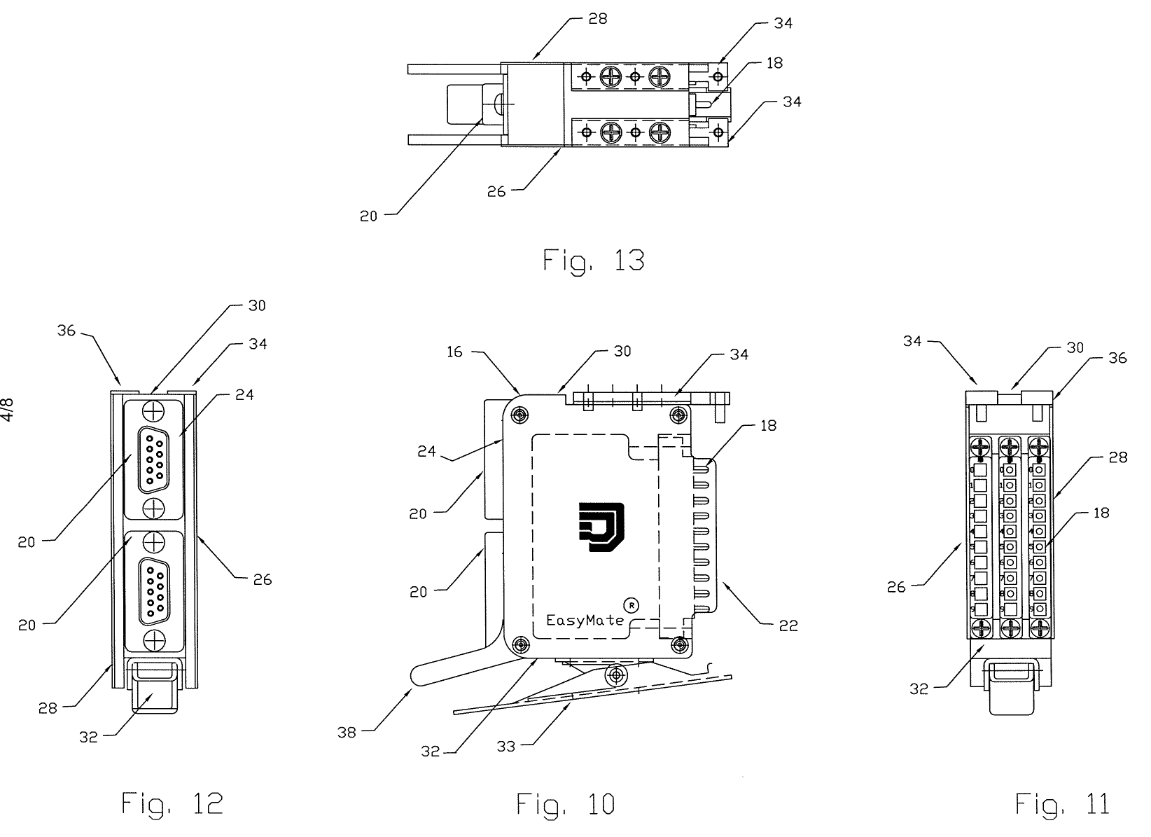

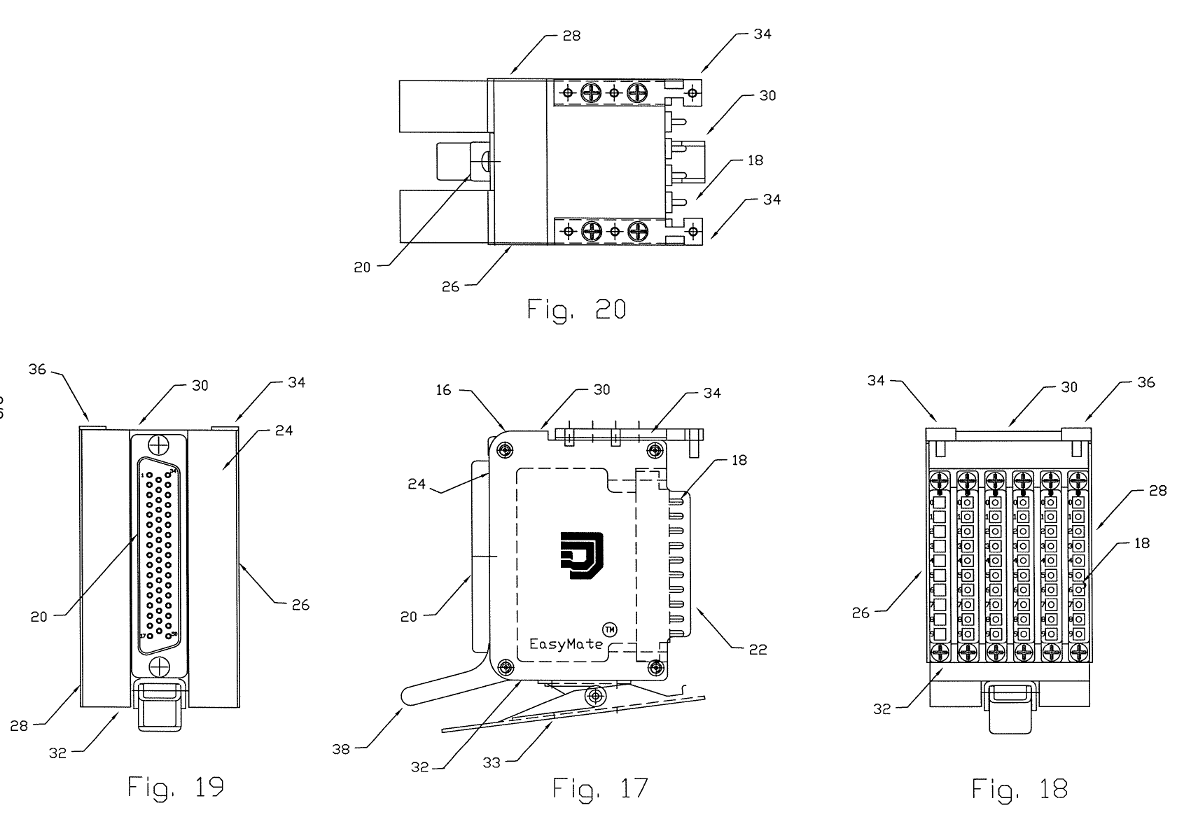

The adapter 10 may even include multiple connectors on the second (rear) side 24 of the body for connecting with more than one cable to be tested or a single cable to be tested with multiple connectors. For example, as illustrated in FIGS. 10-13, the rear side 24 may be equipped with two 9 pin connectors for coupling with a wiring cable that terminates in these types of connectors. In yet another embodiment illustrated in FIGS. 17-20, the rear side 24 may be equipped with a single 50 pin rectangular connector. The particular number and configuration of connectors on the adaptor can be selected to accommodate any testing need.

In use, several of the adapters 10 may be provided for coupling with several wiring cables to be tested. For example, a first adapter with a round 55 pin connector and a second adapter with a rectangular 50 pin connector may be simultaneously used to couple a pair of wiring cables to be tested to the wiring analyzer. The relatively small size, low cost, and durability of the adapters makes it convenient and economical to provide a separate adapter for each connector type on the cables to be tested. The adapters can be easily and safely stored without significant risk of damage when not in use and can be used in any combination and quantity to accommodate any testing requirement. Because of the compact size and durability of the bodies of the adapters, many adapters can be stored in a small cabinet, case, or other enclosure.

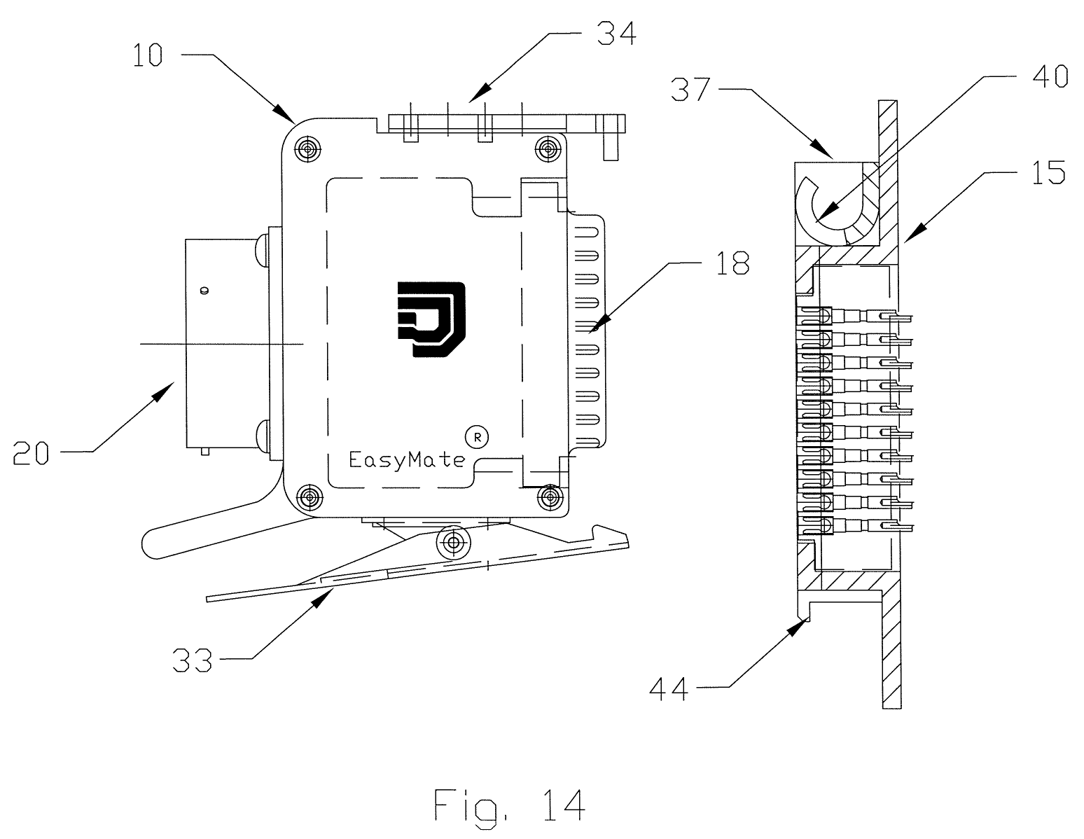

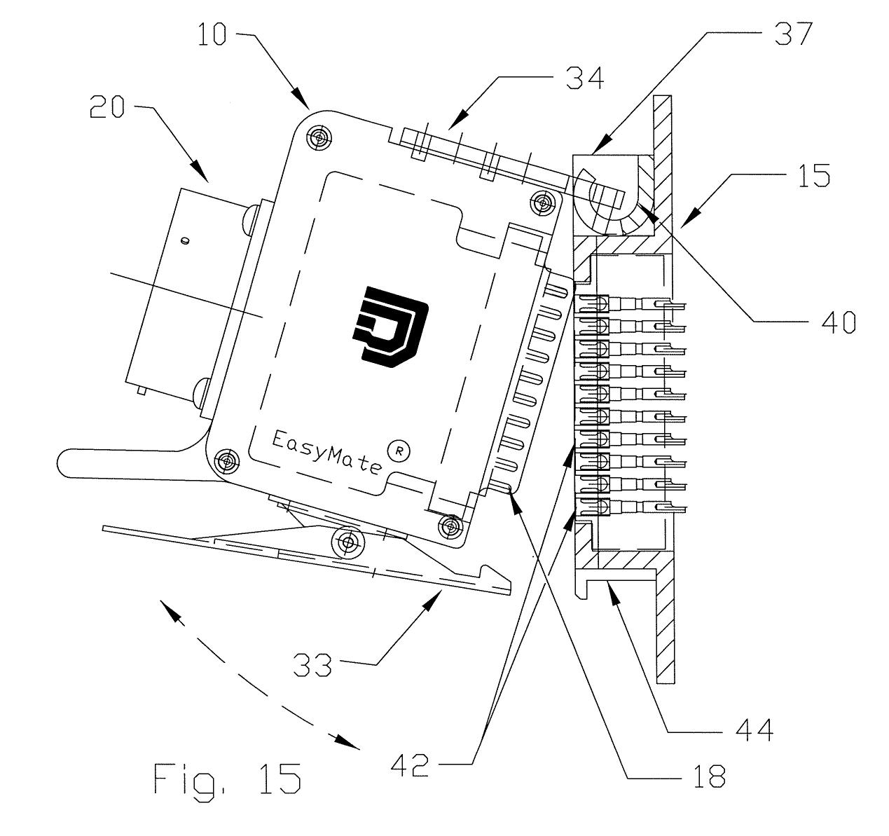

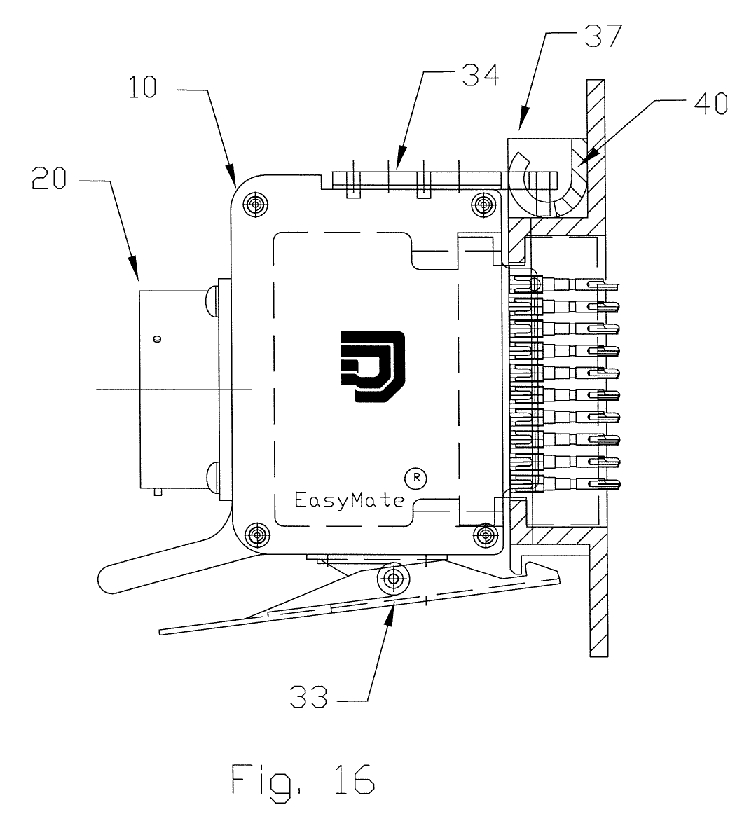

To attach one of the adapters 10 to the wiring analyzer 14, the adapter is first carried to the wiring analyzer or its interface 15 as depicted in FIG. 14. The top of the adapter is then tilted toward the interface as depicted in FIG. 15 so that the bars 34, 36 of the hanging structure are received within hooks 40 of the rack 37. The bottom of the adapter is then pivoted toward the interface about the hanging structure so that the first set of contacts 18 on the front side of the adapter are received within corresponding sockets 42 or receivers on the interface. While the pins of the first set of contacts are being seated in the sockets 42 of the interface, the latch 33 is pivoted to its open position and then released to its biased, closed position so that its teeth engage a locking rail 44 on the lower edge of the interface as depicted in FIG. 16.

A wiring cable to be tested is then coupled with the adapter 10 by connecting the connector on the end of the wiring cable to the connector or other electrical contacts 20 on the rear side of the adapter. The wiring analyzer then tests the wiring cable connected to the adapter in a conventional manner. Once the testing is complete, the wiring cable is disconnected from the adapter 10 and the adapter is then removed from the wiring analyzer by shifting the latch 33 to its open position, pivoting the lower end of the adapter away from the wiring analyzer interface as shown in FIG. 15, and then lifting the bars of the hanging structure out of the rack. The adapter 10 may then be stored for future use.

Although the invention has been described with reference to the preferred embodiment illustrated in the attached drawing figures, it is noted that equivalents may be employed and substitutions made herein without departing from the scope of the invention as recited in the claims.

Having thus described the preferred embodiment of the invention, what is claimed as new and desired to be protected by Letters Patent includes the following:

1. An adapter for connecting a wiring cable to be tested to a wiring analyzer, the adapter comprising:
a body;
a first set of contacts positioned on a first side of the body for electrically connecting with the wiring analyzer; and
a second set of contacts positioned on a second side of the body and electrically connected to the first set of contacts for connecting with a connector on the cable to be tested.

2. The adapter as set forth in claim 1, wherein the body includes hanging structure for hanging the adapter on an interface of the wiring analyzer.

3. The adapter as set forth in claim 2, wherein the first and second sides of the body are less than 4 inches apart so that the first set of contacts is positioned less than 4 inches from the second set of contacts.

4. The adapter as set forth in claim 1, wherein the first set of contacts comprises a plurality of electrically conductive pins for connecting with a plurality of female-type electrical connectors on an interface of the wiring analyzer.

5. The adapter as set forth in claim 1, wherein the second set of contacts are contained within at least one connector mounted on the second side of the body.

6. The adapter as set forth in claim 1, wherein the body is generally rectangular in cross-section and formed of rigid material.

7. The adapter as set forth in claim 2, wherein the body includes a latch for securing the adapter to the interface.

8. An adapter for connecting a wiring cable to be tested to a wiring analyzer, the adapter comprising:
a body having first and second opposed sides spaced less than 4 inches apart and hanging structure for hanging the adapter on the wiring analyzer;
a plurality of electrically conductive pins positioned on the first side of the body for electrically connecting with an interface of the wiring analyzer; and
a first connector positioned on the second side of the body and electrically connected to the pins for connecting with a first connector on the cable to be tested.

9. The adapter as set forth in claim 8, further including a second connector positioned on the second side of the body and electrically connected to the pins for connecting with a second connector on the cable to be tested.

10. The adapter as set forth in claim 9, wherein the first and second sides of the body are less than 3 inches apart so that the electrically conductive pins are positioned less than 3 inches from the first and second connectors.

11. The adapter as set forth in claim 8, wherein the body is generally rectangular in cross-section and formed of rigid material.

12. The adapter as set forth in claim 8, wherein the body includes a latch for securing the adapter to the interface.

13. A wiring testing assembly comprising:
a wiring analyzer having a switch matrix and an interface electrically connected with the switch matrix;
a first adapter for connecting a first wiring cable to be tested to the wiring analyzer, the first adapter comprising:
a body having first and second opposed sides and hanging structure for hanging the adapter on the wiring analyzer;
a plurality of electrically conductive pins positioned on the first side of the body for electrically connecting with the interface of the wiring analyzer; and
a connector positioned on the second side of the body and electrically connected to the pins for connecting with a connector on the first cable to be tested; and
a second adapter for connecting a second wiring cable to be tested to the wiring analyzer, the second adapter comprising:
a body having first and second opposed sides and hanging structure for hanging the adapter on the wiring analyzer;
a plurality of electrically conductive pins positioned on the first side of the body for electrically connecting with an interface of the wiring analyzer; and
a connector positioned on the second side of the body and electrically connected to the pins for connecting with the a connector on the second cable to be tested.

14. The wiring testing assembly as set forth in claim 13, wherein the bodies of the first and second adapter are generally rectangular in cross-section and formed of rigid material.

15. The wiring testing assembly as set forth in claim 13, wherein the bodies of the first and second adapters each include a latch for securing the adapters to the interface.

16. The wiring testing assembly as set forth in claim 13, wherein the bodies are less than 4 inches thick.
